(19) United States
(12) Patent Application Publication
(10) Pub. No.: US 2016/0150650 A1
(43) Pub. Date: May 26, 2016

(54) PRINTED CIRCUIT BOARD WITH ELECTRONIC COMPONENT EMBEDDED THEREIN AND METHOD FOR MANUFACTURING THE SAME

(71) Applicant: Samsung Electro-Mechanics Co., Ltd., Suwon-si (KR)

(72) Inventor: Jung-Hyun CHO, Busan (KR)

(73) Assignee: Samsung Electro-Mechanics Co., Ltd., Suwon-si (KR)

(21) Appl. No.: 14/945,074

(22) Filed: Nov. 18, 2015

(30) Foreign Application Priority Data
Nov. 20, 2014 (KR) 10-2014-0162293

(51) Int. Cl. H05K 1/18; H05K 1/11; H05K 3/46; H05K 3/00; H05K 3/32; H05K 1/14; H05K 1/09

(52) U.S. Cl. CPC H05K 1/183; H05K 1/144; H05K 1/181; H05K 1/115; H05K 1/111; H05K 1/09; H05K 3/0017; H05K 3/0044; H05K 3/32; H05K 3/4697

(57) ABSTRACT

Disclosed are an electronic component-embedded printed circuit board and a method of manufacturing the same. An electronic component-embedded printed circuit board includes a laminated structure comprising resin insulation layers and conductive layers laminated alternately, a via formed in the resin insulation layers and electrically connecting the conductive layers to one another, a plurality of connection terminals formed on one surface of the laminated structure, a cavity formed on the other surface of the laminated structure, and an electronic component inserted in the cavity, and a depressed portion in which a surface of the electronic component exposed through an opening of the cavity is depressed in comparison to the other surface of the laminated structure.

### CROSS-REFERENCE TO RELATED APPLICATIONS

This application claims the benefit under 35 USC 119(a) of Korean Patent Application No. 10-2014-0162293, filed on Nov. 20, 2014, in the Korean Intellectual Property Office, the entire disclosure of which is incorporated herein by reference for all purposes.

### BACKGROUND

1. Field

The following description relates to a printed circuit board with an electronic component embedded therein and a manufacturing method thereof.

2. Description of Related Art

With the recent decrease in the size of electronic products, there exists a demand for producing thinner and highly integrated circuit boards for packages used in the electronic products. Printed circuit boards having electronic devices embedded therein have emerged to cope with the demand. With this technology, thin packages are produced to make the printed circuit board thinner.

Electronic component embedded printed circuit boards are generally formed through an embedding process, which involves forming a cavity in a core substrate, placing an electronic component such as, for example, an IC, a MLCC, a capacitor or an inductor, in the cavity and then fixing the electronic component in the cavity by use of a filler or the like.

Then, a buildup layer made of an insulation layer may be laminated on an upper surface and a lower surface of the core substrate on which the electronic component is mounted. A copper thin layer may be then formed on the buildup layer, and the copper thin layer may be patterned to form a circuit pattern.

Moreover, the printed circuit board having a number of electronic components mounted thereon has a pad formed thereon for electrical connection, and the pad may be electrically connected to the circuit pattern through a via formed in the buildup layer.

However, because the core substrate needs to have a cavity formed therein in order to have an electronic component embedded therein in the conventional electronic component embedded printed circuit board, it is not possible to lower the manufacturing costs and to simplify the manufacturing processes due to the inevitable process of forming the cavity in the core substrate.

Although it is possible to form the cavity in the core substrate through a mechanical process such as, for example, laser drilling or CNC drilling, or an exposing process, it is difficult to form a fine cavity or to adjust the depth of the cavity due to an increased roughness after the mechanical process or the exposing process that is performed. An example of such a printed circuit board is provided in Japan Patent Publication No. 2013-150013.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic component-embedded printed circuit board including a laminated structure including resin insulation layers and conductive layers laminated alternately, a via formed in the resin insulation layers and electrically connecting the conductive layers to one another, a plurality of connection terminals formed on one surface of the laminated structure, a cavity formed on the other surface of the laminated structure, and an electronic component inserted in the cavity, and a depressed portion in which a surface of the electronic component exposed through an opening of the cavity is depressed in comparison to the other surface of the laminated structure.

The laminated structure may further include a solder resist layer having an opening, through which a plurality of connection terminals are exposed.

The plurality of connection terminals may comprise an IC connection terminal and a passive component connection terminal. The IC connection terminal may be disposed on a center portion of the laminated structure. The passive component connection terminal may be disposed over an outer portion of the IC connection terminal.

The depressed portion may be formed by a step formed between the surface of the electronic component exposed through the opening of the cavity and the other surface of the laminated structure in which the cavity is formed.

In the laminated structure, a pad may be arranged along the depressed portion, and an electrical connection member may be adhered to the pad.

The electronic component may be a capacitor, a thin-film inductor, a resistor, a high frequency filter or a compact fuse.

The cavity may have a polygonal shape.

The printed circuit board may include a coreless multilayered printed circuit board having an electronic component embedded therein.

An upper package or a lower package may be coupled to another package to form a package of package (POP) structure.

An electronic component mounted in the another package may be inserted in the depressed portion.

In yet another general aspect, a method of manufacturing a printed circuit board involves forming plating layers on a carrier, mounting a coin between the plating layers of the carrier, forming an insulation layer such that the plating layers and the coin are buried under the insulation layer, forming a via in the insulation layer and forming a circuit layer on the insulation layer, separating the carrier from a laminated structure comprising the insulation layer and the circuit layer, forming a depressed portion in the laminated structure at one side in which the depressed portion is formed by removing an exposed metal layer of the coin and exposing copper thin-films of the plating layers by use of etching, and forming a solder resist layer on the laminated structure at a side opposite to the one side in which the depressed portion is formed.

The general aspect of the method may further involve preparing the carrier prior to the forming of the plating layers on the carrier, the preparing of the carrier involving forming a copper thin-film on an upper surface of the carrier.

In the forming of the plating layers on the carrier, the plating layers may include a barrier layer. The plating layers may be formed in an order of sequentially laminating copper, nickel and copper. The nickel may be used for the barrier layers.

In the mounting of the coin, the coin may include a metal layer, a passive component in a thin-film form and a barrier layer formed between the metal layer and the passive component. The metal layer may be mounted such that the metal layer is in contact with the copper thin-film of the carrier.

In the forming of the insulation layer, the insulation layer may be laminated on the carrier. A cavity may be formed in the insulation layer such that the coin is inserted in the cavity.

In the forming of the insulation layer, the insulation layer may be formed by forming a first insulation membrane so as to cover the plating layers and then forming a second insulation membrane so as to cover an upper surface of the coin over the first insulation membrane.

The first insulation membrane and the second insulation membrane may be made of different insulation materials, and the second insulation membrane may be laminated on the first insulation membrane.

After the forming of the via in and the circuit layer on the insulation layer, a buildup layer may be further formed on the insulation layer, and the method may further include repeating the forming of the via in and the circuit layer on the buildup layer.

In the removing of the metal layer of the coin and the copper thin-films of the plating layers, the coin and the plating layers each may include a barrier layer, and the barrier layer may be used as an etching barrier.

After the removing of the metal layer of the coin and the copper thin-films of the plating layers, the method may further include etching the barrier layer included in the coin and the plating layers by use of a nickel etching solution.

Other features and aspects will be apparent from the following detailed description, the drawings, and the claims.

### BRIEF DESCRIPTION OF DRAWINGS

FIG. 1 is a cross-sectional view illustrating an example of an electronic component-embedded printed circuit board.

FIG. 2 is a cross-sectional view illustrating another example of an electronic component-embedded printed circuit board.

FIGS. 3A and 3B are cross-sectional views of an example of a POP package using an electronic component embedded printed circuit board. FIG. 3A is a cross-sectional view illustrating the example of the electronic component-embedded printed circuit board that is used as an upper package. FIG. 3B is a cross-sectional view illustrating the example of the electronic component-embedded printed circuit board that is used as a lower package.

FIGS. 4A to 4L show the processes of an example of a method of manufacturing an electronic component-embedded printed circuit board. FIG. 4A is a cross-sectional view illustrating an example of a step of preparing a carrier. FIGS. 4B and 4C are cross-sectional views illustrating an example of a step of forming a plating layer. FIG. 4D is a cross-sectional view illustrating an example of a step of mounting an electronic component. FIGS. 4E to 4G are cross-sectional views illustrating an example of a step of forming a circuit layer after an insulation layer is formed. FIG. 4H is a cross-sectional view illustrating an example of a step of forming a buildup layer. FIG. 4I is a cross-sectional view illustrating an example of a step of removing the carrier. FIGS. 4J and 4K are cross-sectional views illustrating an example of a step of forming a pad. FIG. 4L is a cross-sectional view illustrating an example of a step of forming a solder resist layer.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

The terms used in the present specification are merely used to describe various examples, and are not intended to limit the present description. An expression used in the singular encompasses the expression of the plural, unless it has a clearly different meaning in the context. In the present specification, it is to be understood that the terms such as “including” or “having,” and the like, are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Terms such as “first”, “second”, “one surface (side)” and “the other surface (side)” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

Unless otherwise defined, all terms used herein, including technical or scientific terms, have the same meanings as those generally understood by those with ordinary knowledge in the field of art to which the present description belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Certain embodiments of the present description will be described below in detail with reference to the accompanying drawings. Those components that are the same or are in correspondence are rendered the same reference numeral regardless of the figure number, and redundant descriptions are omitted. Before describing certain embodiments of the present description, a general principle and a system for obtaining 3-dimensional information using holography will be first described below.

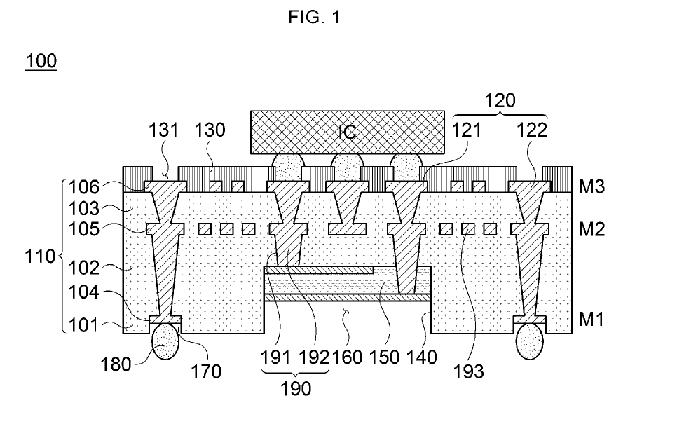

FIG. 1 illustrates an example of an electronic component-embedded printed circuit board.

Referring to FIG. 1, the electronic component-embedded printed circuit board 100 does not have a core layer, but is constituted as a laminated structure 110 to form a multilayered printed circuit board. In this example, resin insulation layers 101, 102 and 103 and conductive layers 104, 105 and 106 are alternately laminated on one another to form the laminated structure 110. The resin insulation layers 101, 102 and 103 may be made of substantially the same resin insulation material, and the conductive layers 104, 105 and 106 may made of copper. This multi-layered printed circuit board may constitute as a coreless printed circuit board.

In this example, the resin insulation layers 101, 102 and 103 are formed by a photocurable or thermosetting epoxy insulation material. For example, the resin insulation layers 101, 102 and 103 may be formed by a buildup material made of resin including photosensitive monomers or a cured compound composed substantially of thermosetting epoxy resin. For example, the cured compound that is composed substantially of thermosetting epoxy resin may be 80% or more by weight thermosetting epoxy resin. In the electronic component embedded printed circuit board 100 according to this example, a plurality of connection terminals 120 are arranged on an upper surface of the laminated structure 110, and the plurality of connection terminals 120 may be constituted by an IC connection terminal 121 and a passive component connection terminal 122 such as a condenser and the like. For example, the IC connection terminal 121 may be disposed in an array on a center portion of the upper surface of the laminated structure 110, and the passive component connection terminal 122 may be arranged on an outer part of the IC connection terminal 121.

Referring to FIG. 1, a solder resist layer 130 is formed on the upper surface of the laminated structure 110. An opening 131 is formed in the solder resist layer 130 in accordance with the positions of the connection terminals 120, and thus an upper surface of the IC connection terminal 121 and an upper surface of the passive component connection terminal 122 are exposed to the outside through the opening 131 while the IC connection terminal 121 and the passive component terminal 122 are disposed on the upper surface of the laminated structure 110.

In this example, a cavity 140 with a certain depth is also formed in a lower surface of the laminated structure 110. A capacitor 150 is embedded inside the cavity 140, and a lower surface of the capacitor 150 is exposed through an opening of the cavity 140. A step is formed between the lower surface of the capacitor 150 and the lower surface of the laminated structure 110. That is, the lower surface of the capacitor 150 and the lower surface of the laminated structure 110 have a difference in height so that a step is formed between them, thereby forming a depressed portion.

That is, the capacitor 150 being embedded in and in contact with a lower surface of the cavity 140 may be mounted so that the lower surface of the capacitor 150 exposed through the opening of the cavity 140 is not protruded outward from the lower surface of the laminated structure 110 so as to form the step between them. As a result, while the cavity 140 has the capacitor 150 inserted therein, a depressed portion 160, which is where the surface of the capacitor 150 is exposed through the opening of the cavity 140, may be formed.

Moreover, a BGA (Ball Grid Array) type pad 170 is arranged in an array along the depressed portion 160. Also, an electrical connection member 180 such as a solder ball and the like may be adhered to the pad 170. The laminated structure 110 may be directly seated on a mainboard by use of SMD through the electrical connection member 180. The laminated structure 110 may be coupled to another package to form a POP (Package of Package) structure. The POP coupling structure of the laminated structure 110 will be described in further detail below.

The shape of the cavity 140 may be determined in accordance with the shape of planar surface of the capacitor 150. The shape of the planar surface may be a polygonal shape such as, for example, a rectangle or a hexagon. The shape of the planar surface may be formed in an “L” shape in accordance with the arrangement of the capacitor 150. The shape of the cavity 140 may be determined in accordance with the shape or arrangement of the capacitor 150. For example, the shape of the cavity 140 may be a polygonal shape such as a rectangle or a hexagon. However, the shape of the cavity 140 shall not limited to these examples, and any shape may be introduced to the cavity 140 as long as it is a shape that is capable of having an IC or passive component mounted on another package inserted therein while the POP structure described above is formed.

A via hole 191 is formed in the resin insulation layers 101, 102 and 103. The inside of the via hole 191 is filled and the upper surface thereof is patterned to form a plating layer 192. A via 190 obtained by the plating layer 192 filling an inside of the via hole 191. The via 190 may have a shaped of being tapered to one direction along its vertical direction. The via 190 is used as an electrical connection for electrically connecting a circuit layer 193, which is formed between the resin insulation layers 101, 102 and 103, a connection terminal 120, which is formed on an upper surface of the laminated structure 110, and a pad 170, which is formed on a lower surface of the laminated structure 110.

For the convenience of description, assuming three resin insulation layers 101, 102 and 103 are laminated to form the laminated structure 110, the resin insulation layers 101, 102 and 103 may be referred to as a M1 layer, a M2 layer and a M3 layer, respectively, with respect to the connection terminal 120, the circuit layer 193 and the pad 170. In this example, one of the vias 190 connected to the circuit layer 193 formed on the M2 layer is connected to the capacitor 150, and another one of the vias 190 is connected to the pad 170 formed on the M3 layer.

Moreover, the circuit layer 193 formed on the M2 layer is connected to the IC connection terminal 121 and the passive component connection terminal 122 formed on the M1 layer.

The via 190 connected to the capacitor 150 inserted in the cavity 140 may be adjusted in a length such that the via 190 is connected to either of both extremity terminals of the capacitor 150.

The connection terminal 120 and the pad 170 formed on the M1 layer and the M3 layer, respectively, are made mostly of copper layers. The solder resist layer 130 and a plating layer (now shown) that is a surface exposed through openings of the resin insulation layers 101, 102 and 103 are made of a material excluding copper. In this example, plating layers formed on exposed areas of the connection terminal 120 and the pad 170 may be nickel-gold plated layers or gold plated layers.

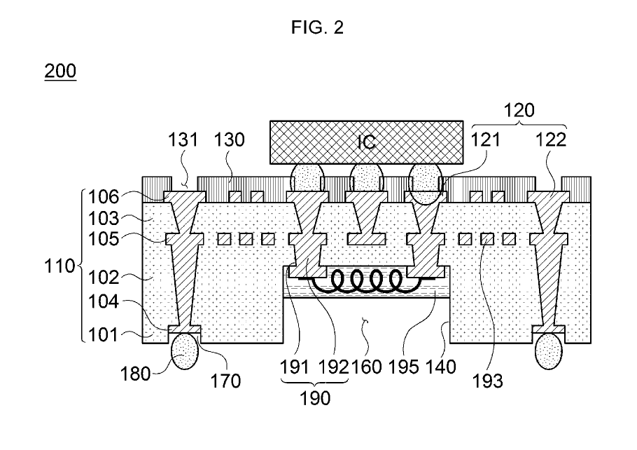

Although FIG. 1 illustrates an example in which an electronic component inserted in a cavity is a capacitor, the present description is not limited to this example. In another example, the electronic component to be inserted in the cavity may be an inductor 195, as shown in FIG. 2. Moreover, in yet another example, the electronic component may be a combined electronic component including a capacitor and an inductor.

FIG. 2 is a cross-sectional view illustrating another example of an electronic component-embedded printed circuit board.

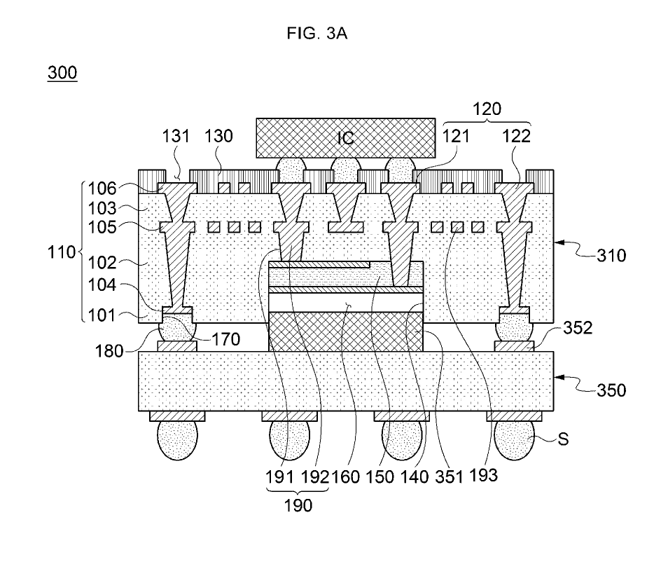

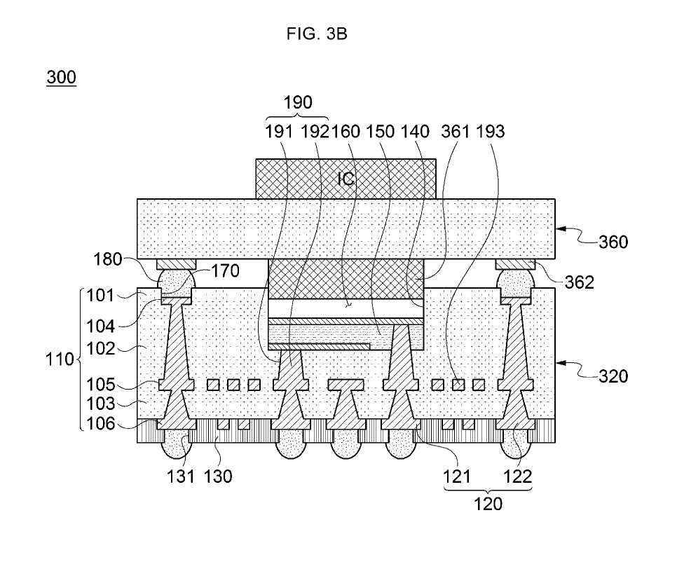

FIGS. 3A and 3B are cross-sectional views of a POP package that uses an example of an electronic component-embedded printed circuit board in accordance with the present description. The electronic component-embedded printed circuit board may be constituted to function as an upper package 310 or a lower package 320 when forming a POP package 300 with reference to FIGS. 3A and 3B.

Referring to FIG. 3A, the electronic component-embedded printed circuit board is constituted as a package for a POP structure when an electronic component mounted on another package is inserted in the depressed portion 160 formed by embedding a passive component such as a capacitor or an inductor in the cavity 140. In this configuration, the total height of the POP package can be minimized, making the POP structure thinner. The depressed portion 160 is formed by a difference in height between the surfaces of electronic components being inserted in the cavity 140 at one surface of the printed circuit board and the surface of the laminated structure 110 adjacent to the cavity 140.

The electronic component-embedded printed circuit board will be described in detail with reference to FIGS. 3A and 3B. Referring to one example of the electronic component-embedded printed circuit board illustrated in FIG. 3A, when the electronic embedded printed circuit board serves as an upper package 310 of the POP structure, an IC is mounted on the solder resist layer 130 over the laminated structure 110 through a solder ball formed on the IC connection terminal 121. In this case, an electronic component 351 mounted on an upper surface of a lower package 350 may be inserted in the depressed portion 160 formed in a lower surface of the laminated structure 110. A passive component 150, such as a thin-film capacitor or a thin-film inductor, inserted in the cavity 140 of the electronic component-embedded printed circuit board, which is the upper package 310 in this example, may be in contact with or spaced from the electronic component 351, which is inserted in the depressed portion 160, of the lower package 150. Then, a pad 170 which is formed adjacent to or around the depressed portion 160 may be coupled to the connection terminal 352 formed on the upper surface of the lower package 350 through the electrical connection member 180.

Referring to another example illustrated in FIG. 3B, in the event that the electronic component-embedded printed circuit board serves as a lower package 320 of the POP structure, the depressed portion 160 formed in the laminated structure 110 is disposed to face upward. That is, the depressed portion 160 is disposed in a face-up manner toward the IC. In this case, an electronic component 361 mounted on a lower surface of an upper package 360 may be inserted in the depressed portion 160. A pad 170 that is formed adjacent to the depressed portion 160 may be coupled to a pad 362 formed on a lower surface of the upper package 360 through an electrical connection member 180, and a plurality of connection terminals 120 formed at a surface opposite to the depressed portion 160 of the laminated structure 110 may be used as pads through an electrical connection member S such as a solder ball and the like.

As such, in the POP structure described above, the electrical component-embedded printed circuit board may be used as the upper package 310 or the lower package 320, and be mounted on a mainboard (not shown). In the example illustrated in FIG. 3B, the electronic component-embedded printed circuit board is used as the lower package 320, and the plurality of connection terminals 120 formed on the laminated structure 110 are used as pads and are mounted directly on the mainboard.

In this example of the electronic component-embedded printed circuit board, a passive component such as a thin-film capacitor or a thin-film inductor and an active component such as an IC and the like may be inserted in a cavity 140. However, the present description is not limited to what is described herein, and various types of electronic components such as resistance, a high frequency filter or a compact fuse may be mounted selectively in the cavity 140.

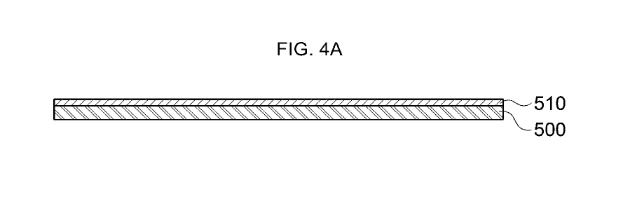

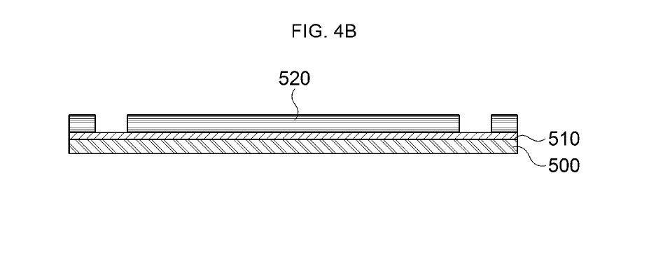

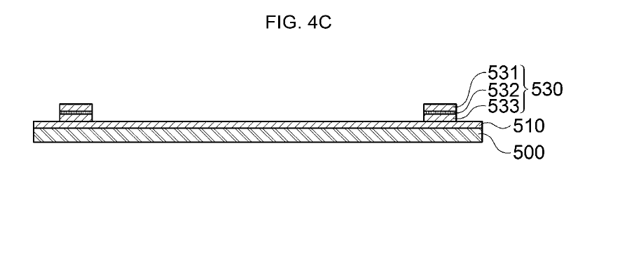

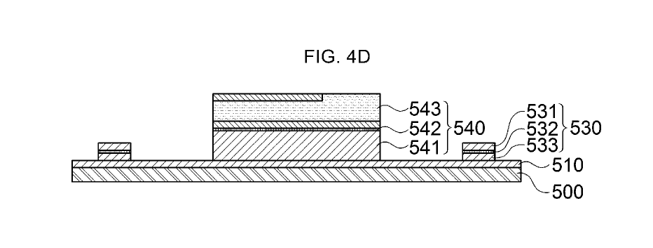

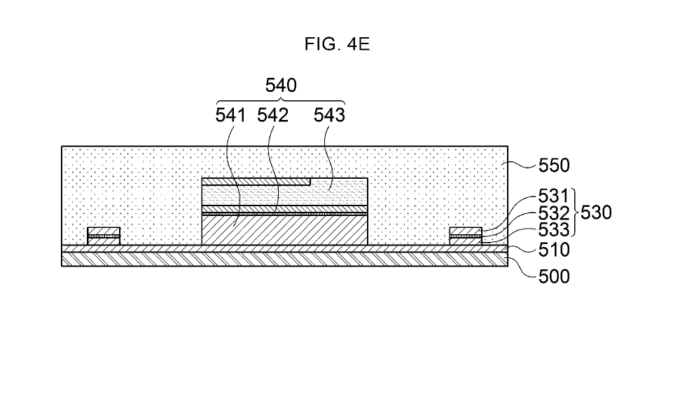

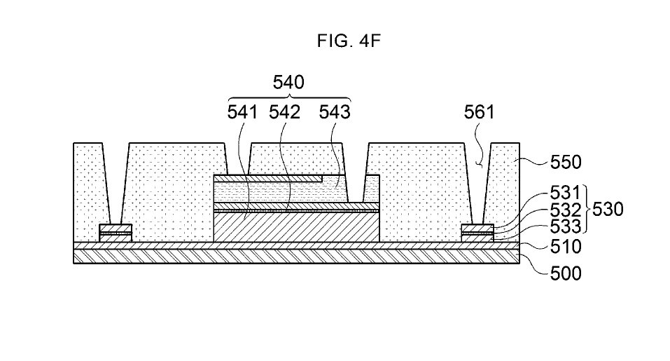

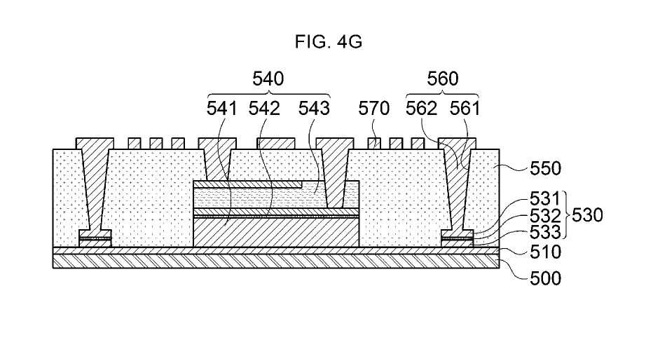

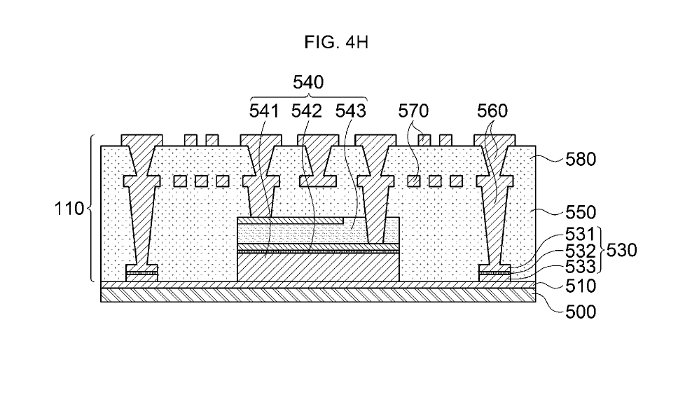

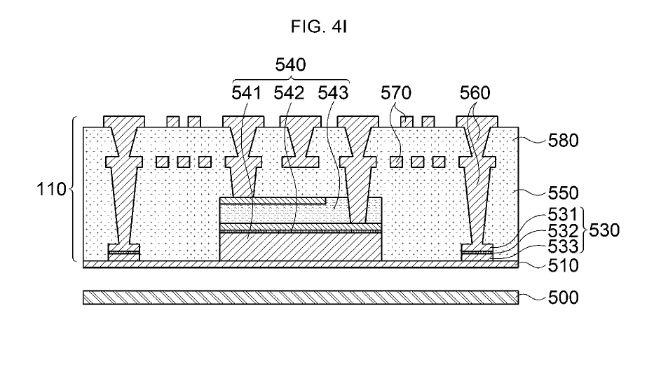

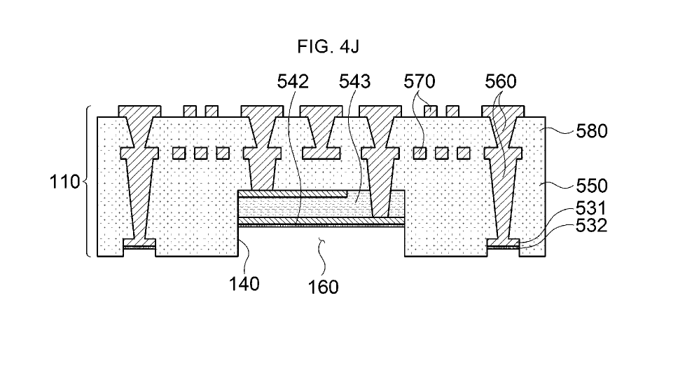

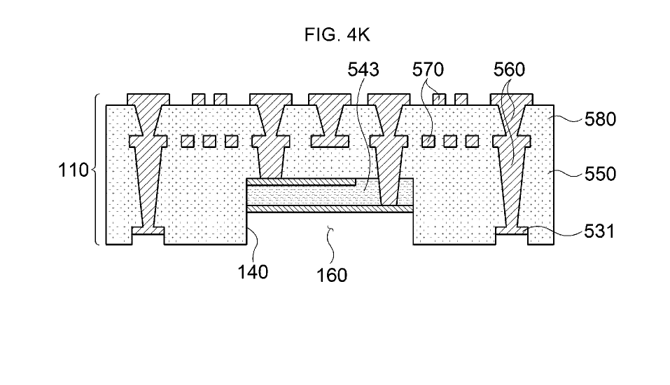

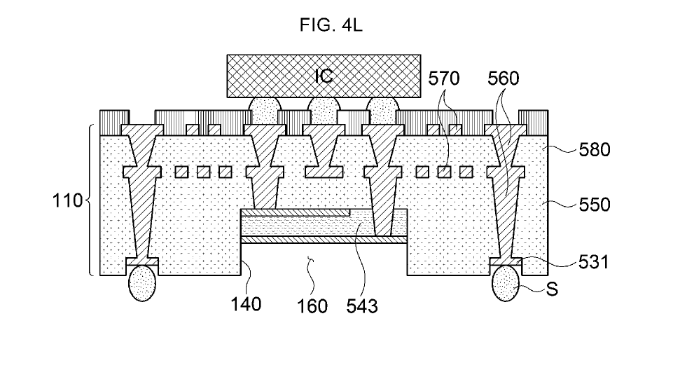

An example of a method of manufacturing an electronic component-embedded printed circuit board that has the structure illustrated above will be described with reference with FIGS. 4A to 4L.

FIGS. 4A to 4L show the processes of an example of a method of manufacturing an electronic component-embedded printed circuit board. FIG. 4A is a cross-sectional view illustrating an example of a step of preparing a carrier. FIGS. 4B and 4C are cross-sectional views illustrating an example of a step of forming a plating layer. FIG. 4D is a cross-sectional view illustrating an example of a step of mounting an electronic component. FIGS. 4E to 4G are cross-sectional views illustrating an example of a step of forming a circuit layer after an insulation layer is formed. FIG. 4H is a cross-sectional view illustrating an example of a step of forming a buildup layer. FIG. 4I is a cross-sectional view illustrating an example of a step of removing the carrier. FIGS. 4J and 4K are cross-sectional views illustrating an example of a step of forming a pad. FIG. 4L is a cross-sectional view illustrating an example of a step of forming a solder resist layer.

As illustrated in the accompany drawings, in order to implement the electronic component embedded printed circuit board having the structure as described above, a carrier 500 is prepared with reference to FIG. 4A. A copper thin-film 510 or another metal layer laminated on an upper surface of the carrier 500 to prepare the carrier 500. In this example, any other metal layers such as, for example, nickel, other than copper may be used in place of the copper thin-film 510 as the another metal layer.

Next, as illustrated in FIGS. 4B and 4C, a plating layer 530 is formed on the carrier 500. Referring to FIG. 4B, a dry film 520 is coated on the carrier 500 on which the copper thin-film 510 is formed, and then the dry film 520 is patterned. Then, the plating layer 530 is formed over the dry film 520 through a plating process.

Since the plating layer 530 becomes a pad in the final product, the plating layer 530 is formed to include a barrier layer. For this, the plating layer 530 is formed in the order of sequentially laminating copper (Cu, 531 of FIG. 4C), nickel (Ni, 532 of FIG. 4C) and copper (Cu, 533 of FIG. 4C) on one another. In this example, the plating layer 530 is constituted as a laminated structure of copper and nickel in order to subsequently use the nickel metal layer as an etching barrier. The nickel metal layer is not etched by an etching solution when a depressed portion to be formed later is formed in the final product.

Next, as illustrated in FIG. 4D, a coin 540 is mounted on a space between plating layers 530 that are formed on the carrier 500. In this example, the term “coin” is referred to as a laminated structure in which a passive component 543 and a metal layer 541 with a certain thickness are laminated to form the laminated structure. For example, the laminate structure may have a plate-like shape with two planar surfaces and may have a circular, rectangular or polygonal shape in a plan view of the carrier 500. In this example, the coin 540 does not have any positional relationship of electrical connection between any other elements in the processes of manufacturing the electronic component-embedded printed circuit board, but used as an element for manufacturing a package having a passive component already inserted in a cavity thereof when an electronic component of another package is to be mounted in the cavity in the final product. Because the coin 540 is similar to a structure of a conventional coin in which the passive component 543 is laminated on the metal layer 541 while the coin 540 is used for forming the depressed portion 160 in the laminated structure 110 shown in FIG. 1 by removing the metal layer 541 constituting the coin 540 in a later process, it will be referred to as a coin in the following description.

In the coin 540, a barrier layer 542 may be formed between the metal layer 541 and the passive component 543 and used as an etching barrier. The barrier layer 542 is made of nickel. However, it is also possible that the barrier layer 542 may be made of a different metal material other than nickel as long as the barrier layer 542 is not removed when an etching process is performed to remove the copper thin-film 510 in a later process.

The passive component 543 may be a capacitor or a thin inductor. The coin 540 is mounted such that the metal layer 541 is in contact with the copper thin-film 510 of the carrier 500.

Next, referring to FIG. 4E, a first insulation layer 550 is formed on the carrier 500, and the first insulation layer 550 is coated in such a way that the coin 540 and the plating layers 530 formed around the coin 540 are completely buried by the first insulation layer 550. In this example, the first insulation layer 550 is coated such that a height of the first insulation layer 550 is higher than that of the coin 540. The first insulation layer 550 may be formed by laminating insulation layers in which a cavity to be inserted by the coin 540 is formed. Moreover, the first insulation layer 550 may be formed by repeatedly coating insulation materials at least twice in accordance with types of the insulation materials being used. That is, a first insulation membrane is coated so as to cover the plating layer 530 first, and then a second insulation membrane is coated so as to cover the passive component 543 of the coin 540 until an upper surface of the coin 540 is completely buried, thereby forming the first insulation layer 550. The first insulation membrane and the second insulation membrane may be made of a same material. However, the present description is not restricted to this example, and the first and second insulation membranes may be made of different materials. For example, the second insulation membrane constituting the first insulation layer 550 may be made of prepreg having a reinforcing member include therein.

Next, referring to FIGS. 4F and 4G, a via hole 561 is formed, and then a plating layer 562 is formed by plating the inside and outside of the via hole 561. Then, the plating layer is etched to form a via 560 and a circuit layer 570. The via 560 is electrically connected to the plating layer 530 formed on the carrier 500 and the circuit layer 570. The via 560 is also electrically connected to the passive component 543 included in the coin 540. Accordingly, a length of the via 560 may vary in accordance with positions of electrodes of the plating layer 530 and the passive component 543.

Next, referring to FIG. 4H, a second insulation layer 580 is laminated on the first insulation layer 550, and then the same forming of the via 560 and the circuit layer 570 described above is repeated to form the laminated structure 110. The second insulation layer 580 is constituted by a plurality of buildup layers, and the plurality of buildup layers may be formed through a laminating process in which a third insulation layer or a four insulation layer is repeatedly laminated to form a multilayered stacking structure in accordance with the intended number of layers of the printed circuit board.

Next, referring to FIG. 4I, the carrier 500 is removed from a lower surface of the laminated structure 110. Then, referring to FIG. 4J, the metal layer 541 of the coin 540 and the copper thin-film of the plating layer 530 are removed from the lower surface of the laminated structure 110 through an etching process. Because the barrier layers 532 and 542 are formed in the plating layer 530 and the coin 540, respectively, while the barrier layers 532 and 542 are made of nickel, which is not etched by a copper etching solution, the barrier layers 532 and 542 function as etching barriers so that only the copper thin-film 533 of the plating layer 530 and the metal layer 541 of the coin 540 are removed.

Accordingly, the depressed portion 160 is formed in the lower surface of the laminated structure 110 by removing the metal layer 541 of the coin 540. Then, the passive component 543 may be maintained in the depressed portion 160 while being inserted in and coupled to the first insulation layer 550.

The copper thin-film 533 of the plating layer 530 and the metal layer 541 may be removed by a same etching process. For example, sulfuric acid, hydrogen peroxide, copper shloride, or the like may be used as an etching solution.

Next, referring to FIG. 4K, the barrier layers 532 and 542, which are used as etching barriers, of the laminated structure 110 are etched by use of a nickel etching solution. Then, referring to FIG. 4L, a solder resist layer 590 is coated on an upper surface of the laminated structure 110. During this step, openings are formed in the solder resist layer 590 so that some portions of the circuit layers 570 formed on the laminated structure 110 are exposed through the openings. Thus, the circuit layers 570 function as connection terminals being in contact with an IC or a passive component. Moreover, the plating layer 530 exposed around the depressed portion 160 functions as a pad on which an electrical connection member S such as, for example, a solder ball or the like, is to be mounted.

In the electronic component-embedded printed circuit board manufactured through the processes described above, the metal layer 541 of the coin 540 having the passive component 543 included therein is removed by use of etching. By using the etching process, the cavity 140 in which the passive component 543 is embedded is formed. According to the present example, it is unnecessary to use a mechanical process or exposing and developing processes to form the depressed portion 160 when the depressed portion 160 is formed over an exposed surface of the passive component 543. In this example, it is possible that the shape of the depressed portion 160 is formed almost the same as that of the coin 540. Accordingly, through the processes described herein, the depressed portion 160 is formed more precisely with a desired shape because vertical and horizontal side surfaces of the depressed portion 160 are formed in perpendicular shapes with no wear during the forming the depressed portion 160.

Moreover, as described earlier, since the depressed portion 160 formed in the lower surface of the laminated structure 110, which is a first package, has an electronic component of another package, which is a second package, of a POP package inserted therein, the overall height of the POP package may be minimized, making the POP package thinner.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic component-embedded printed circuit board comprising:
a laminated structure comprising resin insulation layers and conductive layers laminated alternately;
a via formed in the resin insulation layers and electrically connecting the conductive layers to one another;
a plurality of connection terminals formed on one surface of the laminated structure;
a cavity formed on the other surface of the laminated structure, and an electronic component inserted in the cavity; and
a depressed portion in which a surface of the electronic component exposed through an opening of the cavity is depressed in comparison to the other surface of the laminated structure.

2. The printed circuit board of claim 1, wherein the laminated structure further comprises a solder resist layer having an opening, through which a plurality of connection terminals are exposed.

3. The printed circuit board of claim 2, wherein the plurality of connection terminals comprises an IC connection terminal and a passive component connection terminal, the IC connection terminal is disposed on a center portion of the laminated structure, and the passive component connection terminal is disposed over an outer portion of the IC connection terminal.

4. The printed circuit board of claim 1, wherein the depressed portion is formed by a step formed between the surface of the electronic component exposed through the opening of the cavity and the other surface of the laminated structure in which the cavity is formed.

5. The printed circuit board of claim 4, wherein in the laminated structure, a pad is arranged along the depressed portion, and an electrical connection member is adhered to the pad.

6. The printed circuit board of claim 1, wherein the electronic component is a capacitor, a thin-film inductor, a resistor, a high frequency filter or a compact fuse.

7. The printed circuit board of claim 1, wherein the cavity has a polygonal shape.

8. The printed circuit board of claim 1, wherein the printed circuit board comprises a coreless multilayered printed circuit board having an electronic component embedded therein.

9. The printed circuit board of claim 1, wherein an upper package or a lower package is coupled to another package to form a package of package (POP) structure.

10. The printed circuit board of claim 9, wherein an electronic component mounted in the another package is inserted in the depressed portion.

11. A method of manufacturing a printed circuit board, comprising:
forming plating layers on a carrier;
mounting a coin between the plating layers of the carrier;
forming an insulation layer such that the plating layers and the coin are buried under the insulation layer;
forming a via in the insulation layer and forming a circuit layer on the insulation layer;
separating the carrier from a laminated structure comprising the insulation layer and the circuit layer;
forming a depressed portion in the laminated structure at one side in which the depressed portion is formed by removing an exposed metal layer of the coin and exposing copper thin-films of the plating layers by use of etching; and
forming a solder resist layer on the laminated structure at a side opposite to the one side in which the depressed portion is formed.

12. The method of claim 11, further comprising:
preparing the carrier prior to the forming of the plating layers on the carrier, the preparing of the carrier comprising forming a copper thin-film on an upper surface of the carrier.

13. The method of claim 11, wherein, in the forming of the plating layers on the carrier, the plating layers comprise a barrier layer;
the plating layers are formed in an order of sequentially laminating copper, nickel and copper; and
the nickel is used for the barrier layers.

14. The method of claim 12, wherein in the mounting of the coin, the coin comprises a metal layer, a passive component in a thin-film form and a barrier layer formed between the metal layer and the passive component; and
the metal layer is mounted such that the metal layer is in contact with the copper thin-film of the carrier.

15. The method of claim 11, wherein in the forming of the insulation layer, the insulation layer is laminated on the carrier; and
a cavity is formed in the insulation layer such that the coin is inserted in the cavity.

16. The method of claim 14, wherein in the forming of the insulation layer, the insulation layer is formed by forming a first insulation membrane so as to cover the plating layers and then forming a second insulation membrane so as to cover an upper surface of the coin over the first insulation membrane.

17. The method of claim 16, wherein the first insulation membrane and the second insulation membrane are made of different insulation materials, and the second insulation membrane is laminated on the first insulation membrane.

18. The method of claim 11, wherein after the forming of the via in and the circuit layer on the insulation layer, a buildup layer is further formed on the insulation layer, and the method further comprises repeating the forming of the via in and the circuit layer on the buildup layer.

19. The method of claim 11, wherein in the removing of the metal layer of the coin and the copper thin-films of the plating layers, the coin and the plating layers each comprises a barrier layer, and the barrier layer is used as an etching barrier.

20. The method of claim 19, wherein after the removing of the metal layer of the coin and the copper thin-films of the plating layers, the method further comprises etching the barrier layer included in the coin and the plating layers by use of a nickel etching solution.
